(19) United States
(12) Patent Application Publication
(10) Pub. No.: US 2024/0162117 A1
(43) Pub. Date: May 16, 2024

(54) POWER ELECTRONICS PACKAGE WITH DUAL-SINGLE SIDE COOLING WATER JACKET

(71) Applicant: SEMICONDUCTOR COMPONENTS INDUSTRIES, LLC, Phoenix, AZ (US)

(72) Inventors: Yoonsoo LEE, Incheon (KR); Seungwon IM, Seoul (KR); Oseob JEON, Seoul (KR)

(73) Assignee: SEMICONDUCTOR COMPONENTS INDUSTRIES, LLC, Phoenix, AZ (US)

(21) Appl. No.: 18/055,123

(22) Filed: Nov. 14, 2022

(51) Int. Cl. H01L 23/473; H01L 25/00; H01L 25/07; H01L 25/18

(52) U.S. Cl. CPC H01L 23/473; H01L 25/071; H01L 25/18; H01L 25/50

(57) ABSTRACT

A package includes a frame having a cooling fluid channel therethrough. The frame has at least one opening in a first sidewall alongside the cooling fluid channel and at least one opening in a second sidewall alongside the cooling fluid channel. A first power electronics module covers the at least one opening in the first sidewall with a surface of a substrate in the first power electronics module being exposed to the cooling fluid channel in the frame through the at least one opening in the first sidewall, and a second power electronics module covers the at least one opening in the second sidewall with a surface of a substrate in the second electronics module being exposed to the cooling fluid channel in the frame through the at least one opening in the second sidewall.

### TECHNICAL FIELD

This disclosure relates to cooling systems for power electronics assemblies.

### BACKGROUND

Effective thermal management of power electronics assemblies or packages is needed for increasing power density and improving reliability in many applications (e.g., in electric drive vehicles). For example, electric and hybrid electric vehicles utilize high voltage battery packs or fuel cells that deliver high power direct current to drive vehicle motors, electric traction systems and other vehicle systems. In addition, these vehicles can include power electronics assemblies (e.g., inverters) to convert the direct current provided by, for example, the battery packs, to alternating current for use by electric motors and other electric devices and systems of the vehicle. A power electronics assembly can include heat-generating semiconductor devices such an insulated-gate bipolar transistor (IGBT) and a fast recovery diode (FRD). Compact packaging of power electronics assemblies creates thermal management challenges that need to be addressed for power-dense systems.

### SUMMARY

In a general aspect, a package includes a frame having a first sidewall and a second sidewall opposite the first sidewall, the frame having at least one opening in the first sidewall and at least one opening in the second sidewall. A first power electronics module covers the at least one opening in the first sidewall with a surface of a substrate in the first power electronics module being exposed to an interior of the frame through the at least one opening in the first sidewall, and a second power electronics module covers the at least one opening in the second sidewall with a surface of a substrate in the second power electronics module being exposed to an interior of the frame through the at least one opening in the second sidewall. The first sidewall, the surface of the substrate of the first power electronics module, the second sidewall, and the surface of the substrate of the second power electronics module collectively define a cooling fluid channel through the frame.

In a general aspect, a package includes a frame having a cooling fluid channel therethrough. The cooling fluid channel is formed between a first sidewall and a second sidewall opposite the first sidewall. The frame includes a first plurality of openings disposed in a first row in the first sidewall alongside the cooling fluid channel and a second plurality of openings disposed in a second row in the second sidewall alongside the cooling fluid channel opposite the first sidewall. A first plurality of power electronics modules are disposed alongside the first sidewall over the first plurality of openings in the first sidewall with each of the first plurality of openings exposing a surface of a substrate in a corresponding one of the first plurality of power electronics modules to the cooling fluid channel in the frame. A second plurality of power electronics modules are disposed alongside the second sidewall over the second plurality of openings in the second sidewall with each of the second plurality of openings exposing a surface of a substrate in a corresponding one of the second plurality of power electronics modules to the cooling fluid channel in the frame.

In a general aspect, a method, includes forming a cooling fluid channel between a first sidewall and a second sidewall in a frame. The frame includes at least one opening in the first sidewall alongside the cooling fluid channel and at least one opening in the second sidewall alongside the cooling fluid channel. The method further includes disposing a first power electronics module to cover the at least one opening in the first sidewall with a surface of a substrate in the first power electronics module being exposed to the cooling fluid channel in the frame through the at least one opening in the first sidewall, and disposing a second power electronics module to cover the at least one opening in the second sidewall with a surface of a substrate in the second power electronics module being exposed to the cooling fluid channel in the frame through the at least one opening in the second sidewall.

In a general aspect, a package includes a frame having a cooling fluid channel therethrough. The cooling fluid channel is formed between a first sidewall and a second sidewall opposite the first sidewall. The frame has at least one opening in the first sidewall alongside the cooling fluid channel and at least one opening in the second sidewall alongside the cooling fluid channel. A first power electronics module covers the at least one opening in the first sidewall with a surface of a substrate in the first power electronics module being exposed to the cooling fluid channel in the frame through the at least one opening in the first sidewall, and a second power electronics module covers the at least one opening in the second sidewall with a surface of a substrate in the second electronics module being exposed to the cooling fluid channel in the frame through the at least one opening in the second sidewall.

### BRIEF DESCRIPTION OF THE DRAWINGS

FIG. 1A schematically illustrates removal of heat from a multiplicity of power electronics modules by a single stream of cooling fluid, in accordance with the principles of the present disclosure.

FIG. 1B illustrates, in a perspective view, an example integrated power electronics package, in accordance with the principles of the present disclosure.

FIG. 1C illustrates an exploded view of the integrated power electronics package of FIG. 1B.

FIG. 1D, FIG. 1E and FIG. 1F illustrate a side view, a bottom view, and an end side view, respectively, of the integrated power electronics package of FIG. 1B.

FIG. 2A illustrates an example power electronics module that is incorporated in the integrated power electronics package of FIG. 1B.

FIG. 2B illustrates pin fins.

FIG. 2C illustrates pin fins including a frustum.

FIG. 3A illustrates an example arrangement of pin fins associated with a pair of power electronic modules disposed on opposite sides of a frame in an integrated power electronics package.

FIG. 3B illustrates another example arrangement associated with multiple pairs of power electronic modules disposed on opposite sides of a frame in an integrated power electronics package.

FIG. 4 illustrates an example method for fabricating an integrated power electronics package as disclosed herein.

In the drawings, which are not necessarily drawn to scale, like reference symbols and or alphanumeric identifiers may indicate like and/or similar components (elements, structures, etc.) in different views. The drawings illustrate, by way of example, but not by way of limitation, various implementations discussed in the present disclosure. Reference symbols and or alphanumeric identifiers shown in one drawing may not be repeated for the same, and/or similar elements in related views in other drawings. Reference symbols and or alphanumeric identifiers that are repeated in multiple drawings may not be specifically discussed with respect to each of those drawings but are provided for convenience in cross reference between related views. Also, not all like elements in the drawings are specifically referenced with a reference symbol and or an alphanumeric identifier when multiple instances of an element are illustrated.

### DETAILED DESCRIPTION

The present disclosure is directed a heat management system for a power electronics package. The power electronics package (e.g., an integrated power module package) may be modular and may include multiple power electronics modules (or sub-packages).

A power electronics module (or sub-package) may, for example, include power electronic devices (e.g., silicon-controlled rectifiers (SCRs), insulated-gate bipolar transistors (IGBTs), field effect transistors (FETs), etc.) to provide AC power to loads. The power electronic devices can be silicon based or based on wide band gap (WBG) semiconductors. The power electronic devices can generate heat which has to be removed to keep the devices at acceptable operating temperatures. For high power density applications (e.g., power density at or greater than 240 kW) the demands for efficient heat removal can be severe.

In example implementations, the power electronics module may include at least a semiconductor die (e.g., an IGBT and/or an FRD). The semiconductor die may be mounted on a top surface of substrate (e.g., a printed circuit board, a direct bonded metal (DBM) substrate, a direct bonded copper (DBC) substrate, etc.). The semiconductor die or dies may be packaged (e.g., encapsulated in a molding compound), for example, as a single side direct cooled (SSDC) power electronics module with signal pins and power terminals extending from the module. The power electronics module may have a width (WM) and a height (HM) along a surface of the substrate, and a thickness (TM) perpendicular (generally perpendicular) to the substrate (in the direction of the semiconductor die mounted on the top surface of substrate). In example implementations, for an IGBT power electronics module, height HM and width WM may be measured in centimeters, while thickness TM may be in the range of a few millimeters or less.

Heat generated by the semiconductor die or dies flows perpendicularly through the substrate for dissipation from a bottom surface of the substrate. In some instances, a heat sink (e.g., a baseplate, or a baseplate with fins) may be attached to the bottom surface of the substrate to aid in dispersal of the heat generated in the power electronics module. The baseplate with fins may include pin fins (i.e., fins shaped like pins). The power electronics module may be further configured with either forced air and liquid cooled options to remove the heat generated in the power electronics module.

In example implementations, an integrated power electronics package may be modular and may include multiple power electronics modules (or sub-packages) in a single package for use in various applications (e.g., three-phase inverters; DC/DC convertors; choppers; half or full bridge; and power supply applications, etc.). For example, an integrated power electronics package for many automotive applications may integrate six IGBT modules in a 6-pack configuration. The multiple power electronics modules (or sub-packages) (e.g., the six IGBT modules) may be placed electrically in parallel.

In example implementations, the integrated power electronics package may include (or be integrated with) a heat management system. The heat management system may utilize a cooling fluid (e.g., water, or a water-glycol mixture) to remove heat generated in the integrated power electronics package. The heat management system may include a manifold or jacket (e.g., a tube or container) including a cooling fluid passageway or channel. The multiple power electronics modules of the integrated power electronics package can be disposed on a side or sides of the cooling fluid channel in contact with the cooling fluid. In example implementations, the manifold or jacket may have a rectangular cylinder shape with a length L between an input end and an output end, and a width W and a height H in a cross-section perpendicular to the length. The manifold or jacket including the cooling fluid channel may be formed in a three-dimensional rectangular frame (a hollow rectangular frame) with an input port and an output port disposed in opposing end plates of the frame. The frame may include windows (e.g., rectangular openings) in a sidewall of the frame. The power electronic modules may be placed over the windows to seal the windows (e.g., using O-rings or other elastomers) and to thereby confine the cooling fluids to the cooling fluid channel within the three-dimensional rectangular frame.

A stream of the cooling fluid can enter the manifold through the inlet port, pass over the multiple power electronics modules placed along the cooling fluid channel in the manifold to remove heat generated by the power electronics modules, and exit the manifold through the output port. The stream of the cooling fluid may be driven by a recirculating pump (not shown).

In some example implementations, an integrated power electronics package may include a multiplicity of power electronics modules placed in sequence in a row. The widths of the multiplicity of power electronics modules placed in sequence in the row in the integrated power electronics package may, for example, extend sequentially module-by-module along a direction of the row while the heights and thicknesses of the power electronics modules may be perpendicular to the direction of the row, in accordance with the principles of the present disclosure.

The multiplicity of power electronics modules placed in sequence in the row may be supported on the frame. The frame may extend in the direction of the row and have windows (openings) exposing the bottom surfaces of the substrates (on the front surfaces of which semiconductor dies are mounted in the power electronics modules) to the interior of the frame (i.e., the cooling fluid channel). Baseplates (e.g., baseplates with pin-fins) if attached to the bottom surfaces of the substrates may protrude (at least the pin fins) on one side of the frame through the windows.

Power terminals and signal pins of each of the multiplicity of power electronics modules placed in the manifold may extend to an outside of the manifold/integrated power electronics package.

In some example implementations, the multiplicity of power electronics modules in the integrated power electronics package may be placed in sequence in two rows (i.e., a first row and a second row) on opposing sides of the frame. The first row and the second row may be separated, for example, by an inter-row distance RD. A first power electronics module placed in the first row may be placed back-to-back with (e.g., opposing) a corresponding second power electronics module placed in the second row. The windows in the frame may expose the bottom surfaces of the substrates on which semiconductor dies are mounted (or the bottom surfaces of the baseplates attached to the substrates) in the power electronics modules disposed on opposing sides of the frame.

A space (defined, e.g., by an inter-row distance) between the first row and the second row in the frame may form a cooling fluid channel for a stream of the cooling fluid from the input port to the output port passing over the backsides of the multiple power electronics modules placed in the first row and the backsides of the multiple power electronics modules placed in the second row on opposing sides of the frame. The cooling fluid channel may provide a single straight continuous path for the stream of the cooling fluid to flow over the backsides of multiple power electronics modules (i.e., without requiring bifurcation or turning of the path to flow over individual power electronics modules).

Baseplate pin fins of the first power electronics module placed in the first row and the baseplate pin fins of the opposing second power electronics module placed in the second row may protrude through the windows or openings in the frame into the cooling fluid channel. The baseplate pin fins of the first power electronics module placed in the first row and the baseplate pin fins of the second power electronics module placed in the second row protruding into the cooling fluid channel may be aligned with each other. In some example implementations, the ends (e.g., a top end) of the pin fins of the opposing power electronics modules may be close to each other in distance (e.g., no greater than 5%-10% of a pin height of the pins), and in some example implementations, the ends of the pin fins of the opposing power electronics modules may even contact or touch each other.

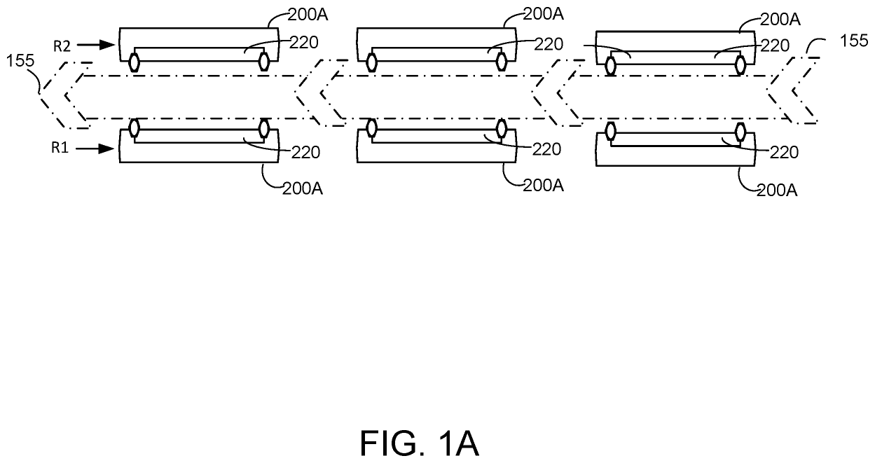

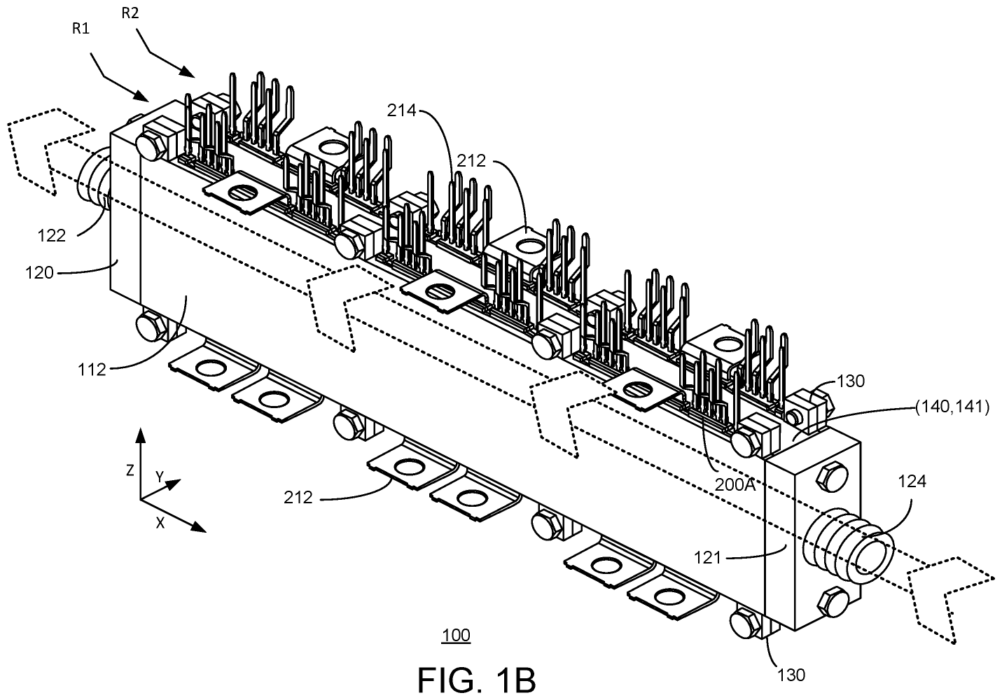

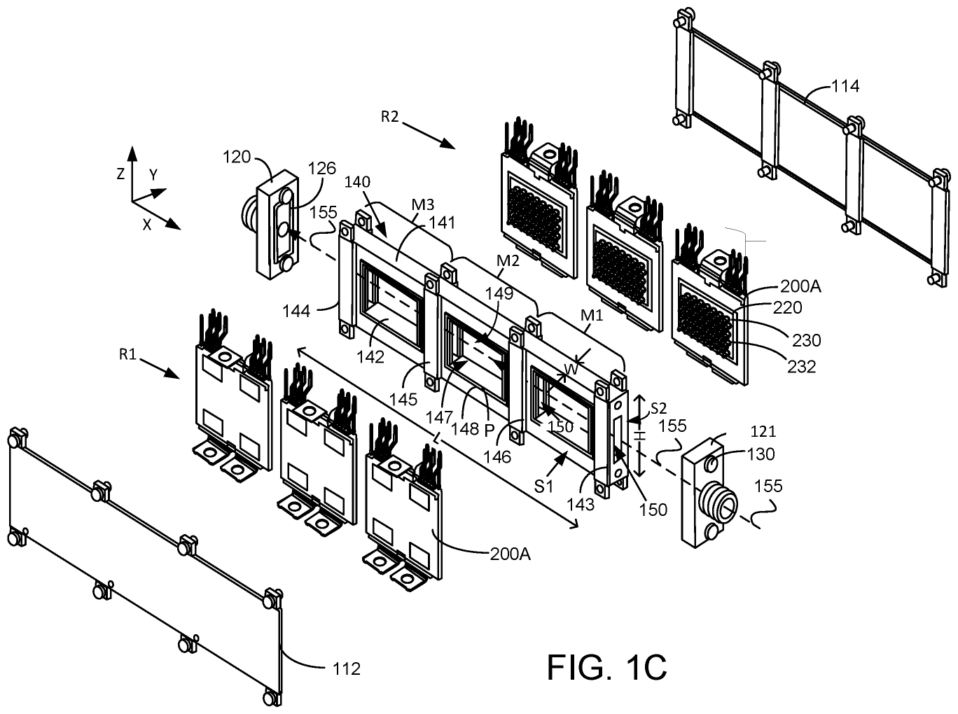

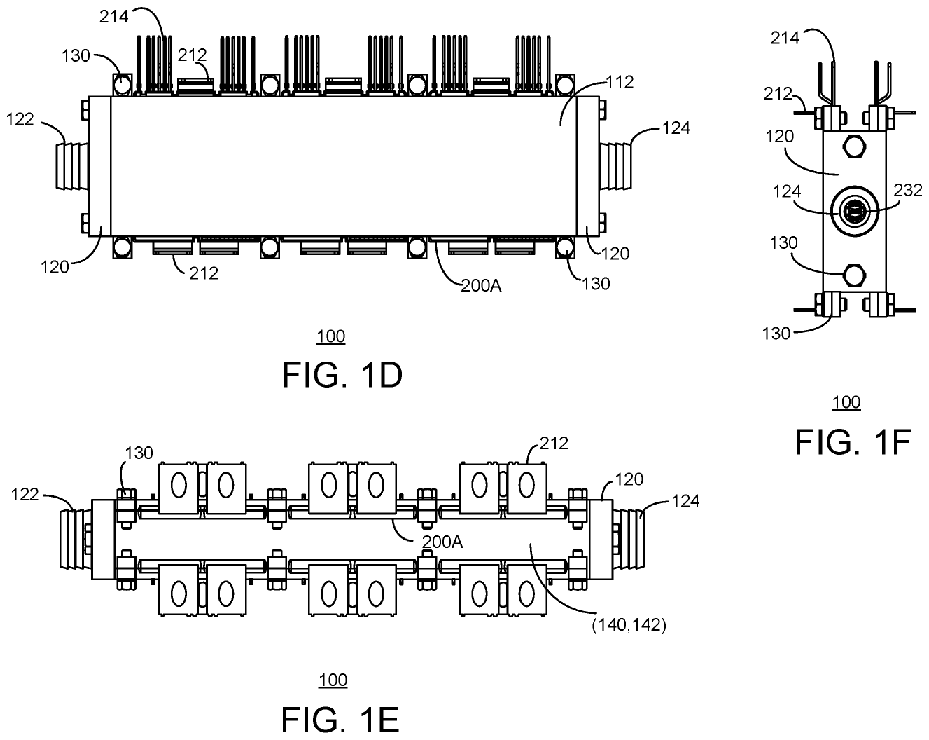

FIG. 1A is a schematic diagram illustrating removal of heat from a multiplicity of power electronics modules by a single stream of cooling fluid. The power electronics modules may, for example, single side direct cooled (SSDC) power electronics modules that have surfaces (e.g., substrate surfaces) for dissipating heat generated by devices in the power electronics modules to an outside of the modules.

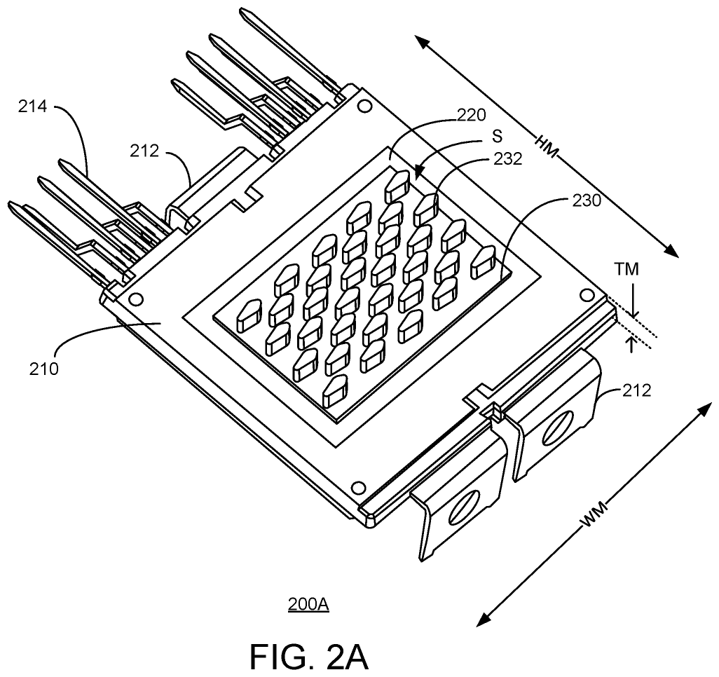

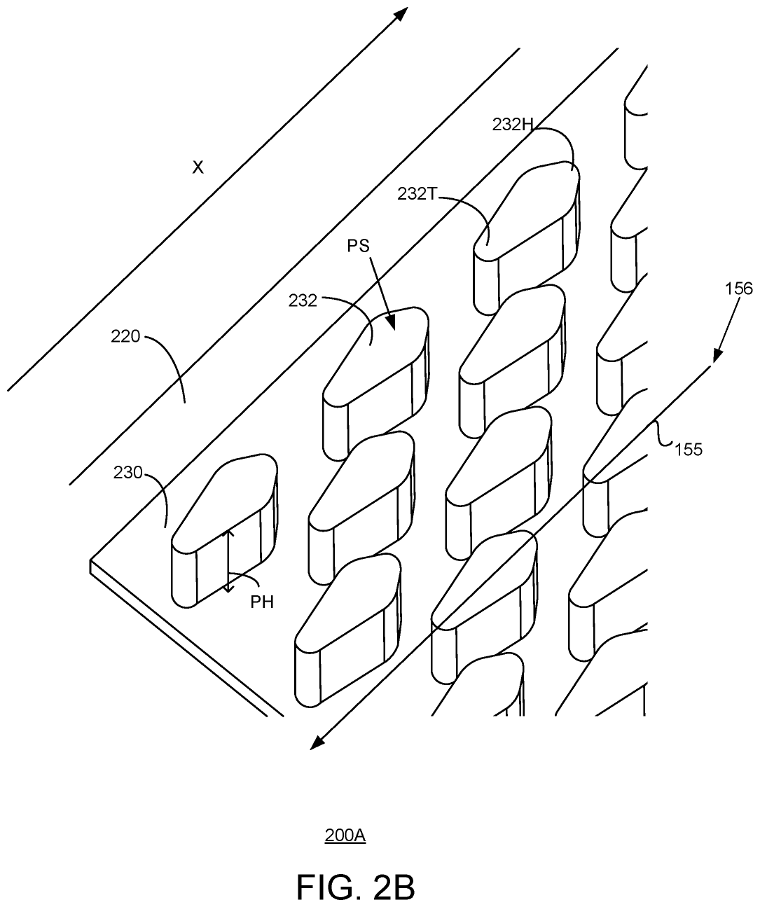

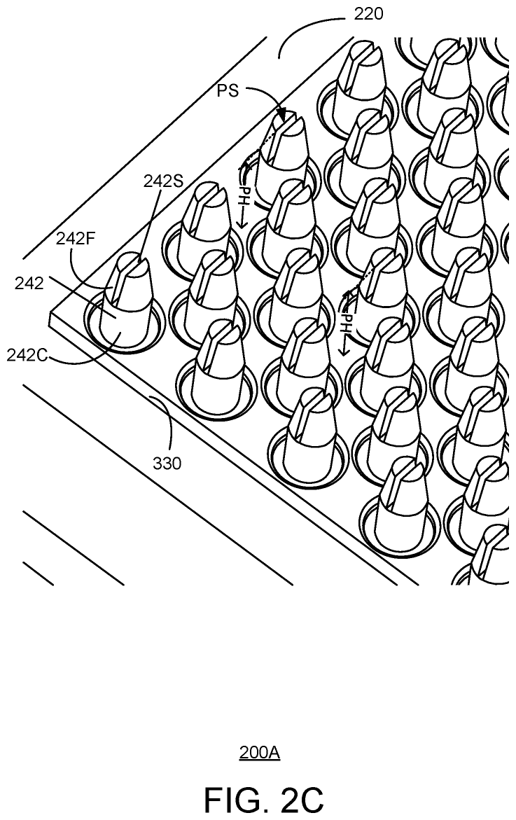

As shown in FIG. 1A, the multiple power electronics modules (e.g., power electronics module 200A, FIG. 2A) may be disposed in sequence in rows (e.g., row R1 and row R2) on either side of a cooling fluid channel 155. The multiple power electronics modules (e.g., power electronics module 200A, FIG. 2A) disposed in both row R1 and row R2 may have substrate surfaces (e.g., substrate 220) exposed to cooling fluid channel 155 for heat removal. In accordance with the principles of the present disclosure, a single stream of cooling fluid may flow across the heat generating (dissipating) surfaces (e.g., substrates 220) of the multiplicity of power electronics modules in sequence in a straight flow path through cooling fluid channel 155 without bifurcations or branching of the flow path.

FIG. 1B shows a perspective side view of an example integrated power electronics package 100, in accordance with the principles of the present disclosure. FIG. 1C shows an exploded view of the integrated power electronics package of FIG. 1B. FIG. 1D, FIG. 1E and FIG. 1F show a top view, a bottom view, and an end side view of the integrated power electronics package of FIG. 1B.

FIG. 2A shows an example power electronics module 200A that can be used in the integrated power electronics package 100 of FIG. 1B. Power electronics module 200A may for example, include a power semiconductor die (e.g., an IGBT) (not shown) mounted on a top surface of a substrate (e.g., substrate 220) and packaged (encapsulated) in an encapsulant 210 (e.g., as an SSDC package). Power electronics module 200A may have the encapsulated portion (encapsulant 210) having a width WM a height HM, and a thickness TM. Power terminals 212 and signal terminals 214 of the power electronics module 200A may extend from the encapsulated portion (encapsulant 210). A heat sink (e.g., baseplate 230) may be attached to a back surface (e.g., surface S) of substrate 220 (e.g., a thermally conductive substrate) to aid in the dispersal of heat generated by the power semiconductor device mounted on the top surface (not shown) of substrate 220. In example implementations, an array of fins (e.g., pin fin 232) may extend outwardly (e.g., perpendicularly) from baseplate 230.

With reference to FIGS. 1B through 1E, in example implementations, integrated power electronics package 100 may be a six-pack of six individual power electronics modules (e.g., power electronics module 200A).

FIG. 1B shows integrated power electronics package 100 having a rectangular box-like shape between two end plates (e.g., end plate 120) attached to opposing ends of a hollow frame (e.g., frame 140). The two end plates may, for example, be aligned along planes that are generally perpendicular to cooling fluid channel 155 (e.g., a longitudinal direction along the fluid channel) in frame 140. two end plates (e.g., end plate 120) may have ports (e.g., input port 124, and output port 122) for flowing a stream of cooling fluid through cooling fluid channel 155 in the frame. The two end plates (e.g., end plate 120, end plate 121 may have an O-ring-and-groove arrangement (e.g., O-ring 126) so that attachment of the two end plates to the opposing ends of the hollow frame can be sealed.

In example implementations, multiple individual power electronics modules (e.g., power electronics module 200A) may disposed (e.g., in rows R1 and R2) along two sides of frame 140. In the view shown in FIG. 1A, only power terminals (e.g., power terminals 212) and signal terminals (e.g., signal terminals 214) of the power electronics modules (e.g., power electronics module 200A) included in integrated power electronics package 100 are visible. The bodies of the power electronics module 200A (e.g., in row R1) are not visible in the view shown in FIG. 1A because they may be hidden under a cover plate (e.g., cover plate 112 shown in FIG. 1C, for example) of the integrated power electronics package 100. Also, only a top beam (e.g., beam 141) of frame 140 is visible in FIG. 1A. The top beam (e.g., beam 141) blocks a view of the bodies of the power electronics module 200A (e.g., in row R1 or row R2) included in frame 140.

In some example implementations, the various structural components of integrated power electronics package 100 (e.g., beams, cover plates, end plates, etc.) may be assembled using, for example, nut-and-bolt assemblies (e.g., nut-and-bolt assembly 130). In some example implementations, the various structural components of integrated power electronics package 100 may also be assembled using, adhesives, O-ring and groove arrangements, or other coupling members (not shown in FIG. 1A).

FIG. 1C shows an exploded view of the various the various structural components of integrated power electronics package 100.

As shown in FIG. 1C, a manifold or jacket formed by frame 140 may include a cooling fluid channel (cooling fluid channel 155) that can carry a stream of cooling fluid to remove heat from the multiple power electronics modules (e.g., 6 power electronics module 200A) included integrated power electronics package 100. The six power electronics modules may be arranged in rows (e.g., rows R1 and R2) on two sides of the manifold or jacket formed by frame 140 (i.e., three modules on each side).

As shown in FIG. 1C, frame 140 may have a six-sided hollow rectangular box-like structure with two sides formed by longitudinal beams (e.g., beam 141 and beam 142) of length L extending in the x direction, two sides formed by sidewalls (e.g., side wall S1) in the x-z plane, and two sides formed by vertical end posts (e.g., end post 144, end post 143) having a height H extending in the z direction.

In some implementations, the cooling fluid channel 115 can be defined at least in part by the frame 140 and the sidewalls of the power modules 200A, which are coupled to the frame 140. In some implementations, the cooling fluid channel 115 can be defined at least in part by the frame 140 and pairs of the power modules 200A on opposing sides of the frame 140. In some implementations, less power modules can be included in the device.

Beam 141 and beam 142 may held apart (in the y direction) by the vertical posts (e.g., end post 144, end post 143) having a height H. End post 144 and end post 143 may be attached to beam 141 and 142 at the ends of frame 140 separated the length L of the frame. Further, vertical side posts (e.g., side post 145 and side post 146) may be attached to beam 141 and 142 along the length L of frame 140 to define areas for openings or windows (e.g., window 147) in the sidewalls (e.g., sidewall S1) of frame 140. The windows (e.g., window 147) may be open to the interior of frame 140, which includes the cooling fluid channel (cooling fluid channel 155). Further, the end posts (e.g., end post 143 and end post 144) may include openings (e.g., slot 150) that provide access to the interior of frame from directions (e.g., x direction) along the length of frame 140.

In some implementations, the slot 150 can have a rectangular profile. Multiple slots, similar to slot 150, can be defined within the frame 140. In example implementations, frame 140 may have a modular structure. For example, frame 140 may include a modules M,1, M2, M3, etc., arranged in a row. The cooling fluid channel (cooling fluid channel 155) may pass through each of the modules in sequence. The modules (e.g., modules M,1, M2, M3, etc.) may be interconnected by slots (like slot 150) through which the cooling fluid channel (cooling fluid channel 155) can pass from one module to the next module (e.g., module M1 to module M2, etc.).

Each module (e.g., module M1) may include a window (e.g., window 147) formed in a sidewall (e.g., sidewall S1) on one side of the frame and a corresponding window (e.g., window 149) formed in another sidewall (e.g., sidewall S2 parallel to sidewall S1) on an opposite side of the frame. Windows 147 and window 149 may be aligned with each other (e.g., aligned to be parallel to each other).

Each individual power electronics module (e.g., power electronics module 200A) disposed (e.g., in rows R1 and R2) along two sides of frame 140 may cover (close) and seal a respective opening or window (e.g., window 147) in the sidewalls (e.g., sidewall S1) of frame 140. In example implementations, an O-ring-and-groove arrangement (e.g., O-ring-and-groove arrangement 148) may be disposed around a perimeter P of the opening or window (e.g., window 147). The O-ring-and-groove arrangement between the power electronics module (e.g., power electronics module 200A) and the sidewall (e.g., sidewall S1) of frame 140 may be utilized to seal the opening or window (e.g., window 147) to confine cooling fluids to the cooling fluid channel (cooling fluid channel 155, FIG. 1B) within the three-dimensional hollow rectangular frame (e.g., frame 140).

FIG. 1C also shows cover plates (e.g., cover plate 112, cover plate 114) that may be applied to the sides (e.g., sidewall S1) of frame 140 to cover and protect the power electronics modules (e.g., power electronics module 200A) disposed (e.g., in rows R1 and R2) along two sidewalls of frame 140.

The cover plates 112, 114 may, for example, be aligned along planes that are generally parallel to cooling fluid channel 155 (e.g., a longitudinal direction along the fluid channel) in frame 140.

FIG. 1D shows, for example, a side view of integrated power electronics package 100 of FIG. 1A. In the view shown in FIG. 1C only power terminals 212 and signal terminals 214 of the power electronics modules (e.g., power electronics module 200A) included in the integrated power electronics package 100 are visible. The bodies of the power electronics module 200A (disposed e.g., in row R1) and other details of frame 140 are not visible in the view shown in FIG. 1A because they may be hidden under cover plate 112.

FIG. 1E shows, for example, a bottom view of integrated power electronics package 100 of FIG. 1A. In the view shown in FIG. 1D, only power terminals 212 of the power electronics modules (e.g., power electronics module 200A) included in integrated power electronics package 100 are visible. The bodies of the power electronics module 200A (disposed e.g., in row R1 and row R2) and other details of frame 140 are not visible in the view shown in FIG. 1A because they may be hidden under beam 142 of frame 140.

FIG. 1F shows, for example, an end side view of integrated power electronics package 100 of FIG. 1A (taken, e.g., in the −x direction, FIG. 1B). The view shows the interior of frame 140 as seen through an end port (e.g., input port 124) disposed on an end plate (e.g., end plate 120) for flowing a stream of cooling fluid through frame 140. In particular, the view reveals that an array of fins (e.g., pin fin 232, FIG. 2A) may extend outwardly from the baseplates of the power electronics modules (disposed on either side of frame 140) into cooling fluid channel 155 (FIG. 1B) for the stream of the cooling fluid passing through frame 140 from the input port to the output port.

In some implementations, openings (e.g., lumen) associated with the input port 124 and/or the output port 122 define at least some portion of the cooling fluid channel 115. In some implementations, the input port 124 and/or the output port 122 define at least some portion of the cooling fluid channel 115.

The pin fins (on the baseplates attached to substrates of the power electronics modules) that intrude into the stream of the cooling fluid passing through frame 140 provide additional surface contact areas for transfer of heat from the baseplate to the cooling fluid.

In example implementations, the pin fins (on the baseplates of the power electronics modules) that intrude into the stream of the cooling fluid passing through frame 140 may have hydrodynamic shapes. The hydrodynamic shapes of the pin fins may be designed to encourage laminar flow (e.g., non-turbulent flow) of cooling fluid across the baseplates (e.g., baseplate 230) and through the array of pin fins of the power electronics modules disposed on either side of cooling fluid channel 155 in frame 140.

In some example implementations, the hydrodynamic shape of a pin fin may be a fish-like (or a teardrop-like) shape.

FIG. 2B (which is an exploded view of a portion of the view of the example power electronics module previously shown in FIG. 2A) shows fish-like or teardrop-like shaped pin fins (e.g., pin fin 232) disposed on a baseplate (e.g., baseplate 230) attached to a substrate (substrate 220) of a power electronics module. As shown in FIG. 2B, pin fin 232 can have a fish-like (or teardrop-like shape with a head portion 232H and a tail portion 232T. Pin fin 232 may have a flat top surface (e.g., surface PS) at a vertical pin height (e.g., pin height PH) above baseplate 230.

A direction of flow of cooling fluids (in cooling fluid channel 155) across the baseplate, over and through the pin fins (e.g., pin fin 232), is indicated in FIG. 2B by arrow 156 (e.g., in the negative x-direction). In example implementations, baseplate 230 attached to substrate 220 of a power electronics module may be oriented so that the head portions (e.g., head portion 232H) of the pin fins (e.g., pin fin 232) are first into the flow of the cooling fluids (so that the flow of the cooling fluids is in the direction from the head portion 232H to the tail portion 232T).

In some example implementations, the hydrodynamic shape of a pin fin may include a frustoconical portion (i.e., a frustrum). The pin fin may include a cylindrical shaft, a portion of which is tapered to form a truncated cone portion (i.e., the frustrum) at one end of the cylindrical shaft.

FIG. 2C shows an exploded view of a portion of a baseplate (e.g., baseplate 330) with pin fins (e.g., pin fin 242) including a frustum (i.e., a truncated conical shape). The baseplate may be attached to a substrate (substrate 220) of a power electronics module. As shown in FIG. 2C, pin fin 242 may include a cylindrical shaft 242C that tapers into a frustrum 242F. Pin fin 242 may have a flat top surface (e.g., surface PS) on the top of frustrum 242F at a vertical pin height (e.g., pin height PH) above baseplate 330). A slot (e.g., slot 242S) may be formed (e.g., cut) in top surface of frustrum 242F.

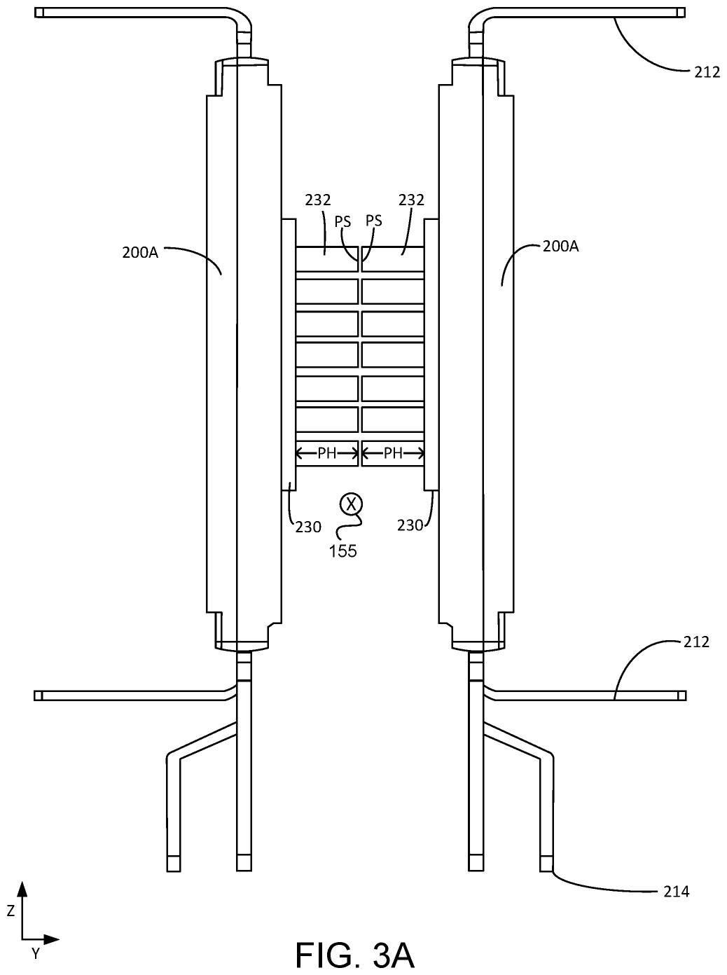

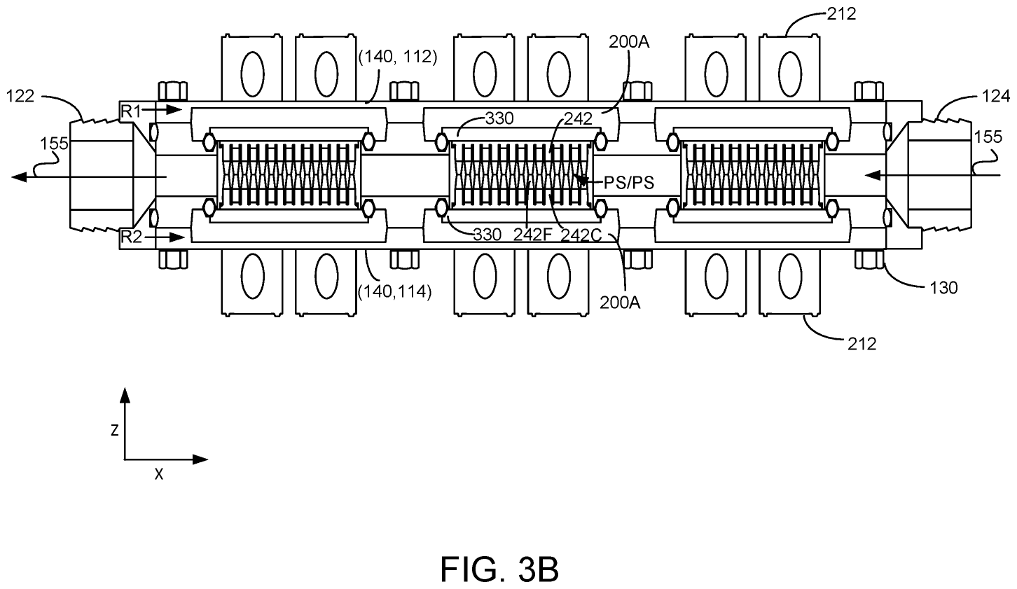

In example assemblies of integrated power electronics package 100, the power electronic modules (e.g., power electronics module 200A) may be positioned so that the top surfaces (e.g., surface PS) of the pin fins (e.g., pin fin 232, or pin fin 242) associated with a pair power electronic modules disposed on opposite sides of frame 140 are close in distance in frame 140 and may even touch each other (as shown, e.g., in FIG. 3A and FIG. 3B).

FIG. 3A shows, for example, a cross-sectional view (in the z-y plane) of an arrangement of pin fins (e.g., pin fin 232) associated with a pair power electronic modules (e.g., power electronics module 200A) disposed on opposite sides of frame 140 in integrated power electronics package 100. For visual clarity, FIG. 3A omits elements of frame 140 and shows only elements of the opposing power electronic modules (e.g., power electronics module 200A). As shown in FIG. 3A, top surfaces (e.g., surface PS) of the fish- or teardrop-like pin fins (e.g., pin fin 232) extending from the baseplates (baseplate 230) of the opposing power electronic modules (e.g., power electronics module 200A) are close in distance along the y axis and can even touch each other.

FIG. 3B shows another example implementation of an arrangement of pin fins (e.g., pin fin 242) extending from the baseplates (baseplate 330) of the opposing power electronic modules (e.g., power electronics module 200A) in integrated power electronics package 100.

FIG. 3B shows a cross-sectional view of integrated power electronics package 100 in the z-x plane. FIG. 3B shows three pairs of power electronics modules (e.g., power electronics module 200A) disposed in rows (e.g., row R1 and row R2) on opposite sides of frame 140. Baseplates 330 attached to the power electronic modules (e.g., power electronics module 200A) may include pin fins (e.g., pin fin 242) that have a cylindrical shaft 242C that tapers into a frustrum 242F. The pin fins of the baseplates of t the power electronic modules (e.g., power electronics module 200A) extend into the cooling fluid channel 155 in frame 140. The pin fins (e.g., pin fin 242) extending from the baseplates (baseplate 330) of opposing power electronic modules (e.g., power electronics module 200A) may be aligned so that ends of the pin fins are close in distance along the z axis and can even touch each other. For example, as shown in FIG. 3B, the top surfaces (e.g., surface PS) of the frustrum (e.g., frustrum 242F) of opposing pin fins can touch each other.

In example implementations, a package includes a frame having a first sidewall and a second sidewall opposite the first sidewall. The frame has at least one opening in the first sidewall and at least one opening in the second sidewall. The frame may be made of metal, plastic, or composite material.

A first power electronics module covers (e.g., closes, seals) the at least one opening in the first sidewall with a surface of a substrate in the first power electronics module. The surface of the substrate in the first power electronics module is exposed to an interior of the frame through the at least one opening in the first sidewall. Further, a second power electronics module covers (e.g., closes, seals) the at least one opening in the second sidewall with a surface of a substrate in the second power electronics module. The surface of the substrate in the second power electronics module is exposed to the interior of the frame through the at least one opening in the second sidewall.

The first sidewall, the surface of the substrate of the first power electronics module, the second sidewall, and the surface of the substrate of the second power electronics module collectively define a cooling fluid channel through the frame. A stream of cooling fluid can flow in the cooling fluid channel over the surface of the substrate of the first power electronics module and the surface of the substrate of the second power electronics module to remove heat from the power electronics modules.

In some example implementations, a package includes a frame having a cooling fluid channel therethrough. The cooling fluid channel is formed between a first sidewall and a second sidewall opposite the first sidewall. The frame includes a first plurality of openings disposed in a first row in the first sidewall alongside the cooling fluid channel and a second plurality of openings disposed in a second row in the second sidewall alongside the cooling fluid channel opposite the first sidewall.

In the package, a first plurality of power electronics modules may be disposed alongside the first sidewall over the first plurality of openings in the first sidewall with each of the first plurality of openings exposing a surface of a substrate in a corresponding one of the first plurality of power electronics modules to the cooling fluid channel in the frame. Furthermore, a second plurality power electronics modules may be disposed alongside the second sidewall over the second plurality of openings in the second sidewall with each of the second plurality of openings exposing a surface of a substrate in a corresponding one of the second plurality power electronics modules to the cooling fluid channel in the frame.

In some example implementations, a package includes a frame having a cooling fluid channel therethrough. The cooling fluid channel is formed between a first sidewall and a second sidewall opposite the first sidewall. The frame has at least one opening in the first sidewall alongside the cooling fluid channel and at least one opening in the second sidewall alongside the cooling fluid channel.

The package further includes a first power electronics module covering the at least one opening in the first sidewall with a surface of a substrate in the first power electronics module being exposed to the cooling fluid channel in the frame through the at least one opening in the first sidewall, and a second power electronics module covering the at least one opening in the second sidewall with a surface of a substrate in the second electronics module being exposed to the cooling fluid channel in the frame through the at least one opening in the second sidewall.

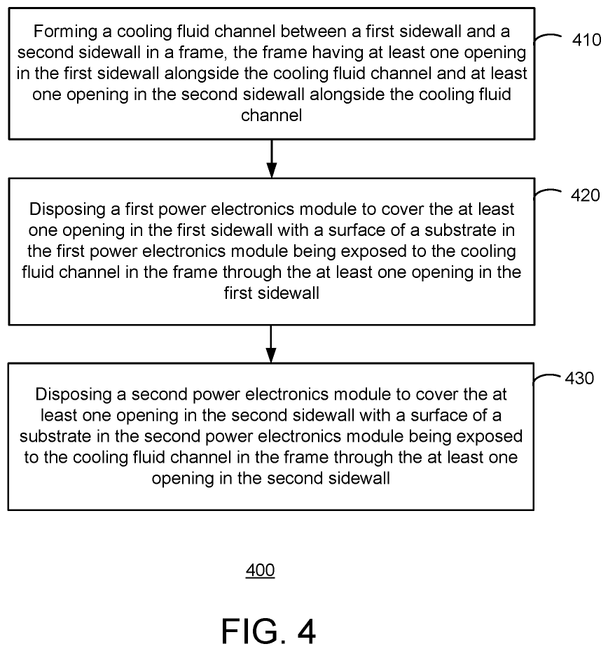

FIG. 4 shows an example method 400 for fabricating an integrated power electronics package 100.

Method 400 includes forming a cooling fluid channel t between a first sidewall and a second sidewall in a frame (410). The frame has at least one opening in the first sidewall alongside the cooling fluid channel and at least one opening in the second sidewall alongside the cooling fluid channel Method further includes disposing a first power electronics module to cover the at least one opening in the first sidewall with a surface of a substrate in the first power electronics module being exposed to the cooling fluid channel in the frame through the at least one opening in the first sidewall (420), and Disposing a second power electronics module to cover the at least one opening in the second sidewall with a surface of a substrate in the second power electronics module being exposed to the cooling fluid channel in the frame through the at least one opening in the second sidewall (430). The first power electronics module and the second power electronics module may, for example, be SSDC packages.

Forming the cooling fluid channel through the hollow frame may include disposing an inlet port on a first end of the hollow frame and an outlet port of a second end of the hollow frame opposite the first end.

Disposing the at least one power electronics module over the at least one opening or window 420 may include sealing of the opening or window by the substrate surface of the power electronics module. Sealing the opening or window may involve disposing an O-ring-and-groove arrangement around a perimeter of the opening or window on the at least one sidewall of the rectangular cylindrical structure. In some implementations, an adhesive (sealant) disposed around the perimeter of the opening or window on the at least one sidewall of the rectangular cylindrical structure may be used to seal the opening.

Disposing the at least one power electronics module over the at least one opening or window 420 may also include attaching a heat sink or baseplate to the substrate surface of the power electronics module. Further, attaching the heat sink or baseplate to the substrate surface of the power electronics module may include exposing the baseplate to the cooling fluid channel in the hollow frame. In example implementations, the baseplate may include at least one pin fin extending from the baseplate. In some example implementations, the at least one pin fin may have a teardrop-like shape. In some example implementations, the at least one pin fin may include a truncated cone portion.

In example implementations, where the at least one sidewall of the rectangular cylindrical structure is a first sidewall, the at least one opening or window is a first window, and the at least one power electronics module is a first power electronic module, method 400 may further include disposing at a second power electronics module over a second window in a second sidewall opposite the first window in the first sidewall so that a substrate surface of second power electronics module covers second window and is exposed to the cooling fluid channel in the hollow frame.

In some example implementations, method 400 may further include aligning a pin fin on a baseplate of the first power electronics module and a pin fin on a baseplate of the second power electronics module so that top end surfaces of the two pin fins touch each other.

In some example implementations, method 400 may further include aligning a pin fin on a baseplate of the first power electronics module and a pin fin on a baseplate of the second power electronics module so that top end surfaces of the two pin fins are separated by a distance no greater than 5% to 10% percent of a pin height.

The various implementations described herein are given only by way of example and only for purposes of illustration. It will understood, for purposes of this disclosure, that when an element, such as a layer, a region, a component, or a substrate, is referred to as being on, mechanically connected to, electrically connected to, coupled to, or electrically coupled to another element, it may be directly on, connected or coupled to the other element, or one or more intervening elements may be present. In contrast, when an element is referred to as being directly on, directly connected to or directly coupled to another element or layer, there are no intervening elements or layers present. Although the terms directly on, directly connected to, or directly coupled to may not be used throughout the detailed description, elements that are shown as being directly on, directly connected or directly coupled can be referred to as such. The claims of the application may be amended to recite exemplary relationships described in the specification and or shown in the figures.

As used in this specification, a singular form may, unless indicating a particular case in the context, include a plural form. Spatially relative terms (e.g., over, above, upper, under, beneath, below, lower, and so forth) are intended to encompass different orientations of the device in use or operation in addition to the orientation depicted in the figures. In some implementations, the relative terms above and below can, respectively, include vertically above and vertically below. In some implementations, the term adjacent can include laterally adjacent to or horizontally adjacent to.

Some implementations may be implemented using various semiconductor processing and/or packaging techniques. Some implementations may be implemented using various types of semiconductor processing techniques associated with semiconductor substrates including, but not limited to, for example, silicon (Si), silicon carbide (SiC), gallium arsenide (GaAs), gallium nitride (GaN), and/or so forth.

While certain features of the described implementations have been illustrated as described herein, many modifications, substitutions, changes, and equivalents will now occur to those skilled in the art. It is, therefore, to be understood that the appended claims are intended to cover all such modifications and changes as fall within the scope of the implementations. It should be understood that they have been presented by way of example only, not limitation, and various changes in form and details may be made. Any portion of the apparatus and/or methods described herein may be combined in any combination, except mutually exclusive combinations. The implementations described herein can include various combinations and/or sub-combinations of the functions, components and/or features of the different implementations described.

What is claimed is:

1. A package comprising:
a frame having a first sidewall and a second sidewall opposite the first sidewall, the frame having at least one opening in the first sidewall and at least one opening in the second sidewall;
a first power electronics module covering the at least one opening in the first sidewall with a surface of a substrate in the first power electronics module being exposed to an interior of the frame through the at least one opening in the first sidewall; and
a second power electronics module covering the at least one opening in the second sidewall with a surface of a substrate in the second power electronics module being exposed to an interior of the frame through the at least one opening in the second sidewall,
the first sidewall, the surface of the substrate of the first power electronics module, the second sidewall, and the surface of the substrate of the second power electronics module collectively defining a cooling fluid channel through the frame.

2. The package of claim 1, wherein the surface of the substrate in the first power electronics module is a first surface of the substrate, and the first power electronics module is a single side direct cooled (SSDC) package including a power semiconductor device mounted on a second surface of the substrate opposite the first surface of the substrate.

3. The package of claim 1, further comprising:
an inlet port disposed at a first end of the frame; and
an outlet port disposed at a second end of the frame opposite the first end.

4. The package of claim 1, wherein the surface of the substrate in the first power electronics module covering the at least one opening seals the at least one opening in the first sidewall alongside the cooling fluid channel.

5. The package of claim 4, wherein an O-ring-and-groove arrangement is disposed around a perimeter of the at least one opening in the first sidewall to seal the at least one opening.

6. The package of claim 4, an adhesive sealant is disposed around a perimeter of the at least one opening in the first sidewall to seal the at least one opening.

7. The package of claim 1, wherein a baseplate is attached to the surface of the substrate of the first power electronics module exposed to the cooling fluid channel in the frame and the baseplate includes at least one pin fin extending from the baseplate into the cooling fluid channel.

8. The package of claim 7, wherein the at least one pin fin has a teardrop-like shape or includes a truncated cone portion.

9. The package of claim 1, wherein the first power electronics module includes a first baseplate having at least a first pin fin extending therefrom into the cooling fluid channel and the second power electronics module includes a second baseplate having at least a second pin fin extending therefrom into the cooling fluid channel, and wherein the first baseplate and the second baseplate are aligned so that so that a top end surface of the first pin fin touches a top end surface of the second pin fin.

10. The package of claim 1, wherein the first power electronics module includes a first baseplate having at least a first pin fin extending therefrom into the cooling fluid channel and the second power electronics module includes a second baseplate having at least a second pin fin extending therefrom into the cooling fluid channel, and wherein the first baseplate and the second baseplate are aligned so that so that a top end surface of the first pin fin are separated by a distance no greater than 10% percent of a pin height.

11. A package comprising:
a frame having a cooling fluid channel therethrough, the cooling fluid channel being formed between a first sidewall and a second sidewall opposite the first sidewall, the frame including a first plurality of openings disposed in a first row in the first sidewall alongside the cooling fluid channel and a second plurality of openings disposed in a second row in the second sidewall alongside the cooling fluid channel opposite the first sidewall;
a first plurality of power electronics modules disposed alongside the first sidewall over the first plurality of openings in the first sidewall with each of the first plurality of openings exposing a surface of a substrate in a corresponding one of the first plurality of power electronics modules to the cooling fluid channel in the frame; and
a second plurality of power electronics modules disposed alongside the second sidewall over the second plurality of openings in the second sidewall with each of the second plurality of openings exposing a surface of a substrate in a corresponding one of the second plurality of power electronics modules to the cooling fluid channel in the frame.

12. The package of claim 11, wherein a baseplate with pin fins is attached to the surface of the substrate in each of the first plurality of power electronics modules and the surface of the substrate in each of the second plurality of power electronics modules being exposed to the cooling fluid channel in the frame.

13. The package of claim 11, wherein each of the first plurality of power electronics modules and each of the second plurality of power electronics modules is a single side direct cooled (SSDC) package including a power semiconductor device mounted on a surface of the substrate opposite the surface of the substrate exposed to the cooling fluid channel in the frame.

14. The package of claim 11, wherein the first plurality of power electronics modules and the second plurality of power electronics modules each include three single side direct cooled (SSDC) packages.

15. A method, comprising:
forming a cooling fluid channel between a first sidewall and a second sidewall in a frame, the frame having at least one opening in the first sidewall alongside the cooling fluid channel and at least one opening in the second sidewall alongside the cooling fluid channel;
disposing a first power electronics module to cover the at least one opening in the first sidewall with a surface of a substrate in the first power electronics module being exposed to the cooling fluid channel in the frame through the at least one opening in the first sidewall; and
disposing a second power electronics module to cover the at least one opening in the second sidewall with a surface of a substrate in the second power electronics module being exposed to the cooling fluid channel in the frame through the at least one opening in the second sidewall.

16. The method of claim 15, wherein forming the cooling fluid channel includes disposing an inlet port at a first end of the frame and an outlet port at a second end of the frame opposite the first end.

17. The method of claim 16, wherein disposing the first power electronics module to cover the at least one opening in the first sidewall includes sealing of the at least one opening in the first sidewall by the surface of the substrate in the first power electronics module.

18. The method of claim 17, wherein sealing of the at least one opening in the first sidewall by the surface of the substrate in the first power electronics module includes disposing an O-ring-and-groove arrangement around a perimeter of the at least one opening in the first sidewall alongside the cooling fluid channel.

19. The method of claim 17, wherein sealing of the at least one opening in the first sidewall by the surface of the substrate in the first power electronics module includes disposing an adhesive around a perimeter of the at least one opening in the first sidewall alongside the cooling fluid channel.

20. The method of claim 15, wherein disposing the first power electronics module to cover the at least one opening in the first sidewall includes attaching a baseplate to the surface of the substrate in the first power electronics module and exposing the baseplate to the cooling fluid channel in the frame, and wherein the baseplate includes at least one pin fin extending from the baseplate into the cooling fluid channel.

21. The method of claim 20, wherein the at least one pin fin has a teardrop-like shape or includes a truncated cone portion.

22. The method of claim 15, wherein the first power electronics module includes a first baseplate having at least a first pin fin extending therefrom into the cooling fluid channel and the second power electronics module includes a second baseplate having at least a second pin fin extending therefrom into the cooling fluid channel, and wherein the method further includes aligning the first power electronics module and the second power electronics module so that so that a top end surface of at least the first pin fin touches a top end surface of at least the second pin fin.

23. The method of claim 15, wherein the first power electronics module includes a first baseplate having at least a first pin fin extending therefrom into the cooling fluid channel and the second power electronics module includes a second baseplate having at least a second pin fin extending therefrom into the cooling fluid channel, and wherein the method further includes aligning the first power electronics module and the second power electronics module so that so that a top end surface of the at least first pin fin and a top end surface of the at least second pin fin are separated by a distance no greater than 10% percent of a pin height.

24. A package comprising:
a frame having a cooling fluid channel therethrough, the cooling fluid channel being formed between a first sidewall and a second sidewall opposite the first sidewall, the frame having at least one opening in the first sidewall alongside the cooling fluid channel and at least one opening in the second sidewall alongside the cooling fluid channel;
a first power electronics module covering the at least one opening in the first sidewall with a surface of a substrate in the first power electronics module being exposed to the cooling fluid channel in the frame through the at least one opening in the first sidewall; and
a second power electronics module covering the at least one opening in the second sidewall with a surface of a substrate in the second electronics module being exposed to the cooling fluid channel in the frame through the at least one opening in the second sidewall.
